(19) United States
(12) Patent Application Publication
(10) Pub. No.: US 2026/0026208 A1
(43) Pub. Date: Jan. 22, 2026

(54) SUPPORT STRUCTURE AND OPTOELECTRONIC DEVICE

(71) Applicant: COMMISSARIAT A L'ENERGIE ATOMIQUE ET AUX ENERGIES ALTERNATIVES, Paris (FR)

(72) Inventors: Christelle LAUGIER, Grenoble (FR); Benoît RACINE, Grenoble (FR); Stéphane ALTAZIN, Grenoble (FR)

(73) Assignee: COMMISSARIAT A L'ENERGIE ATOMIQUE ET AUX ENERGIES ALTERNATIVES, Paris (FR)

(21) Appl. No.: 19/273,910

(22) Filed: Jul. 18, 2025

(30) Foreign Application Priority Data
Jul. 18, 2024 (FR) 24/07912

(51) Int. Cl. H10K 59/123; H10K 59/12

(52) U.S. Cl. CPC H10K 59/123; H10K 59/1201

(57) ABSTRACT

A support structure and a method for manufacturing such a support structure, and an optoelectronic device including such a support structure; wherein the support structure includes an electronic control device including a control electrode; relief patterns arranged on the control electrode, each of the relief patterns being separated from at least one other of the relief patterns by a distance corresponding to an integer multiple of a predetermined fixed pitch; and a metallic structured electrode arranged so as to have contact areas at which the structured electrode is directly in contact with the control electrode, and spacing areas at each of which the structured electrode is separated from the control electrode by at least one of the relief patterns.

### TECHNICAL FIELD OF THE INVENTION

The present invention relates to the field of optoelectronic devices, in particular for applications requiring high light emission frequencies and/or a high luminance.

More particularly, the invention relates to the light-emitting diodes, for example the organic light-emitting diodes.

### STATE OF THE ART

In the field of optical telecommunications, the need for modulation speed of the optical sources is increasingly important. The light sources are required to have a bandwidth in an increasingly high frequency range. This increase in frequency, however, must not be at the expense of the luminance, which must remain high to maintain a good level of signal transmission.

These demands pose a real challenge for the optoelectronic devices, and particularly for the organic light-emitting diodes (OLEDs). Indeed, one of the parameters that limits the bandwidth is the fluorescence lifetime (corresponding to the time it takes for the OLED to emit light). This time, in the range of a few nanoseconds, depends on the intrinsic characteristics of the molecules responsible for fluorescence. Thus, the bandwidth of OLEDs would be limited to a few hundred MHz.

However, it is known from the state of the art that an effect, called the “Purcell effect”, makes it possible to modify the fluorescence lifetime of a molecule depending on its position in the OLED stack, and in particular the distance separating the emissive layer from one of the OLED electrodes. In particular, it has been shown that the smaller the distance between the emissive layer and the electrode, the shorter the fluorescence lifetime.

Furthermore, reducing the radiative lifetime of a phosphorescent emitter by the Purcell effect makes it possible to increase the lifetime (in the sense of degradation) of the optoelectronic devices.

However, bringing the emissive layer closer to one of the electrodes causes another effect, which is usually desirable to avoid, which is to reduce the extraction of light due to the plasmonic coupling corresponding to the excitation of plasmons at the surface of the electrodes. These plasmons are planar guided modes totally absorbed in the plane of the metal of the electrodes after a certain propagation distance.

In order to extract guided light in plasmonic modes into the air, it is known from the state of the art to structure the electrode.

In the case of OLEDs, in order to limit potential short circuits, it is known from the state of the art to deposit a thick layer of a charge transport material. Although such a solution is satisfactory in that it allows both to limit short circuits and to extract the guided light into the air, the use of a thick layer between the electrode and the stack comprising the emissive layer leads to moving said emissive layer away from the electrode, which therefore prevents the desired Purcell effect from being obtained.

There is therefore a need to find a support structure for an optoelectronic device which allows to have rapid modulation of the light emission while maintaining a high luminance.

### SUBJECT OF THE INVENTION The present invention aims to propose a solution which responds to all or part of the aforementioned problems.

This aim can be achieved thanks to the implementation of a support structure to support a stack of semiconductor layers, the support structure comprising:
an electronic control device comprising a substantially planar control electrode and intended for transmitting an electrical control signal to the stack, the electronic control device being configured to generate the electrical control signal;
relief patterns arranged on the control electrode, each of the relief patterns being separated from at least one other of the relief patterns by a distance corresponding to an integer multiple of a predetermined fixed pitch; and
a metallic structured electrode of a material different from the relief patterns, said structured electrode being arranged so as to have contact areas at which the structured electrode is directly in contact with the control electrode, and spacing areas at each of which the structured electrode is separated from the control electrode by at least one of the relief patterns.

The previously described arrangements make it possible to propose a support structure capable of controlling the actuation of an optoelectronic device by the electronic control device, which makes it possible to carry out a rapid and efficient light emission.

Indeed, the presence of a structured electrode makes it possible to extract light linked to emission modes corresponding to the fixed pitch separating the relief patterns, while guaranteeing a continuity of the structured electrode in contact with a light-emitting layer of the optoelectronic device.

It is therefore well understood that the control electrode and the structured electrode are electrically connected at the contact areas.

It is also well understood that the structured electrode is electrically conductive.

The support structure may further have one or several of the following characteristics, taken alone or in combination.

According to one embodiment, the structured electrode comprises silver. It has been found that the use of such a metal makes it possible to limit the absorption of plasmons in the structured electrode and thus facilitate their extraction.

According to one embodiment, the control electrode is electrically conductive.

According to one embodiment, the relief patterns are electrically insulating.

According to one embodiment, the relief patterns comprise an insulating material.

According to one embodiment, the structured electrode has a substantially constant thickness.

According to one embodiment, the control electrode comprises a contact face on which the relief patterns are disposed.

According to one embodiment, the structured electrode has a lower face facing the contact face of the control electrode, and an upper face opposite the lower face.

According to one embodiment, a height at one of the spacing areas is strictly greater than a height at one of the contact areas adjacent to said spacing area, said heights being measured between the contact face and the upper face, substantially perpendicular to the contact face.

Thus, it is possible to ensure a structuring of the upper face of the structured electrode which is similar to the structuring of the relief patterns.

According to one embodiment, the relief patterns are disposed periodically on the control electrode according to a period corresponding to the same integer multiple of the predetermined fixed pitch.

For example, the relief patterns are disposed periodically according to the predetermined fixed pitch, the integer multiple then being equal to 1.

Thus, the deposition of the relief patterns is easier to implement.

According to one embodiment, the relief patterns are identical.

According to one embodiment, the relief patterns are rounded.

In other words, the relief patterns comprise a rounded surface facing the side opposite the contact face of the control electrode, this rounded surface not having a protruding edge.

This makes it possible to limit the risk of breakage of the structured electrode, particularly when It has a small thickness.

According to one embodiment, the electronic control device comprises a transistor. For example, a CMOS (Complementary Metal-Oxide-Semiconductor) transistor.

Thus, this makes it possible to quickly control the structured electrode by varying the electrical control signal, which is particularly advantageous for high-frequency applications.

According to one embodiment, the transistor is disposed in an internal layer of the support structure and comprises a terminal electrically connected to the control electrode through a conduit (or via) passing through at least a part of a thickness of said internal layer.

According to one embodiment, each relief pattern has a maximum thickness measured transversely to the contact face of the control electrode which is comprised between 50 nm and 250 nm.

According to one embodiment, each relief pattern has a maximum thickness measured transversely to the contact face of the control electrode which is comprised between 10 nm and 250 nm, and more particularly between 30 nm and 100 nm.

Thus, it is possible to ensure that the thickness of the relief patterns is sufficiently low so as not to create an excessively large path difference between the contact areas and the spacing areas.

According to one embodiment, the relief patterns comprise bumps and/or domed ribs, such that the structured electrode has a bumpy and/or corrugated upper face.

Thus, the production of the support structure is simplified.

The aim of the invention can also be achieved thanks to the implementation of an optoelectronic device comprising:
a support structure as described above;
a stack of semiconductor layers disposed on the structured electrode forming a first electrode, said stack comprising at least one light-emitting layer; and
a second electrode disposed on the stack;
   the first electrode and the second electrode being arranged to allow the propagation of the electrical control signal through the stack.

Thus, it is possible to propose an optoelectronic device in which the structuring of the structured electrode makes it possible to minimize the distance separating the light-emitting layer from the structured electrode, while redirecting the light initially coupled to the plasmons out of the optoelectronic device.

The optoelectronic device may further have one or several of the following characteristics, taken alone or in combination.

According to one embodiment, the predetermined fixed pitch is substantially equal to an emission wavelength of the light-emitting layer.

According to one embodiment, the predetermined fixed pitch is comprised between 200 nm and 800 nm.

Thus, it is possible to enable the excitation of a localized plasmon mode at said emission wavelength. The light emission is thus more efficient.

According to one embodiment, the stack of semiconductor layers comprises organic semiconductor layers and at least one organic light-emitting layer.

According to one embodiment, a distance separating the light-emitting layer and the structured electrode is less than 80 nm, and in particular substantially equal to 30 nm.

In this way, it is possible to maximize the Purcell effect, which makes it possible to reduce the lifetime of the molecules present in the light-emitting layer, particularly in the case of fluorescent molecules.

The aim of the invention can also be achieved thanks to the implementation of a manufacturing method for manufacturing a support structure as described above, said manufacturing method comprising:
a provision step in which the electronic control device is made available;
an initial deposition step in which at least one primary layer is deposited on the control electrode of the electronic control device;
a step of forming relief patterns in which portions of said at least one primary layer are removed from the control electrode, said portions having a width measured in a plane parallel to the control electrode, said width corresponding to an integer multiple of a predetermined fixed pitch, the removal of said portions forming, by complementarity, the relief patterns;
an electrode deposition step, in which the structured electrode is deposited on the relief patterns and on the control electrode.

The previously described arrangements make it possible to propose a method for manufacturing a support structure suitable for controlling the actuation of an optoelectronic device by an electronic control device, allowing a rapid and efficient light emission.

The manufacturing method may further have one or several of the following characteristics, taken alone or in combination.

According to one embodiment, the primary layer deposited during the initial deposition step comprises a resin, the step of forming relief patterns then comprising:
an exposure step, in which said resin is exposed through an exposure mask, and
a development step, in which the portions of the primer layer are removed by development in a development solvent to form, by complementarity, the relief patterns.

Thus, it is possible to define the relief patterns on a micrometric or nanometric scale.

According to one embodiment, the initial deposition step comprises the deposition of an interlayer insulating layer on the control electrode then of a resin on the interlayer insulating layer, the step of forming relief patterns then comprising:
an exposure step in which said resin is exposed through an exposure mask,
a development step in which portions of the resin are removed by development in a development solvent to form, by complementarity, intermediate relief patterns, and
an etching step in which the resin and the interlayer insulating layer are etched to form the relief patterns.

The previously described arrangements make it possible to define an alternative method for forming the relief patterns on a micrometric or nanometric scale.

According to one embodiment, the step of forming relief patterns comprises a creep step, implemented after the development step, in which the resin is subjected to a heat treatment at a creep temperature, so as to round the relief patterns or the intermediate relief patterns.

In this way, it is possible to form rounded relief patterns which limit the risk of breakage of the structured electrode, particularly when it has a low thickness.

### SUMMARY DESCRIPTION OF THE DRAWINGS

Other aspects, aims, advantages and characteristics of the invention will appear better on reading the following detailed description of preferred embodiments thereof, given by way of non-limiting example, and made with reference to the appended drawings in which:

FIG. 1 is a schematic sectional view of a support structure according to a particular embodiment of the invention.

FIG. 2 is a schematic sectional view of an optoelectronic device according to a particular embodiment of the invention.

FIG. 3 is a schematic top view of a support structure according to a particular embodiment of the invention.

FIG. 4 is a schematic top view of a support structure according to a particular embodiment of the invention.

FIG. 5 is a schematic view of a manufacturing method according to a particular embodiment of the invention.

FIG. 6 is a schematic view of a manufacturing method according to a particular embodiment of the invention.

FIG. 7 is a schematic view of a method for manufacturing an optoelectronic device according to a particular embodiment of the invention.

### DETAILED DESCRIPTION

In the figures and in the remainder of the description, the same references represent identical or similar elements. In addition, the different elements are not represented to scale so as to favor clarity of the figures. Furthermore, the different embodiments and variants are not mutually exclusive and may be combined with each other.

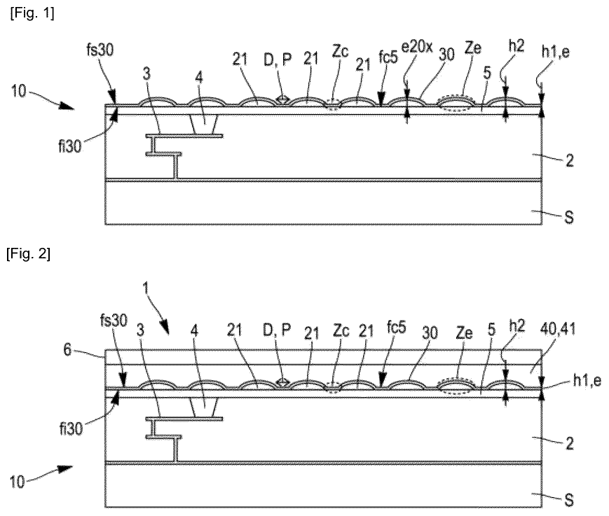

As illustrated in FIGS. 1 to 4, the invention relates to a support structure 10 for supporting a stack 40 of semiconductor layers. The invention also relates to an optoelectronic device 1 comprising such a support structure 10 and such a stack 40.

As can be seen in FIG. 1, the support structure 10 may comprise a substrate denoted “S”, in particular made of glass or silicon, and comprises an electronic control device 3. The electronic control device 3 comprises a substantially planar control electrode 5, which is intended for the transmission of an electrical control signal. The electronic control device 3 is configured to generate said electrical control signal. For example, the electronic control device 3 is configured to vary an electrical control voltage applied to the control electrode 5. The control electrode 5 is generally a metallic electrode which is electrically conductive. For example, the control electrode 5 may comprise a material selected from: silver, a copper-aluminum alloy, titanium nitride, or aluminum. By “substantially planar”, it is meant that the control electrode 5 has a contact face fc5, generally facing the side opposite the substrate S which does not have any curvature. Typically, the contact face fc5 of the control electrode has a roughness less than 5 nm.

To control the control electrode 5, the electronic control device 3 may comprise at least one transistor, for example having a CMOS (Complementary metal oxide semiconductor) structure. The use of such a type of electronic control device 3 makes it possible to form an optoelectronic device 1 having a high speed of modulation of light emission, which is particularly advantageous for the optical telecommunications applications.

As can be seen in FIGS. 1 and 2, the electronic control device 3 may be disposed in an internal layer 2 of the support structure 10, and may comprise a terminal electrically connected to the control electrode 5 through a conduit 4 (or via) passing through at least a part of a thickness of said internal layer 2.

Relief patterns 21 are arranged on the control electrode 5, at the contact face fc5 of the control electrode 5. As a result, certain portions of the control electrode 5 are not covered by relief patterns 21. Although this is not limiting, it is possible for the relief patterns 21 to comprise an insulating material. In this case, the relief patterns 21 are electrically insulating.

Each relief pattern 21 is separated from at least one other of the relief patterns 21 by a distance denoted “D” corresponding to an integer multiple of a predetermined fixed pitch denoted “P”. In the figures, the represented distance D is equal to the fixed pitch P, that is to say the integer multiple is equal to 1. However, such a construction is not limiting, and it is entirely possible for the integer multiple to be greater than 1. For example, the predetermined fixed pitch P is comprised between 200 nm and 800 nm.

Advantageously, and as represented in FIGS. 1 to 4, it is possible for the relief patterns 21 to be disposed periodically on the control electrode 5 according to a period corresponding to the same integer multiple of the predetermined fixed pitch P. For example, the relief patterns 21 can be disposed periodically according to the predetermined fixed pitch P. Thus, the deposition of the relief patterns 21 is simpler to implement. Furthermore, it is possible for the relief patterns 21 to all be identical.

The relief patterns 21 may have an external surface facing the side opposite the control electrode 5 which is rounded. In other words, said external surface does not have a protruding edge. Thus, it is possible to limit the risk of breakage of a structured electrode 30 deposited on the relief patterns 21, which will be described later.

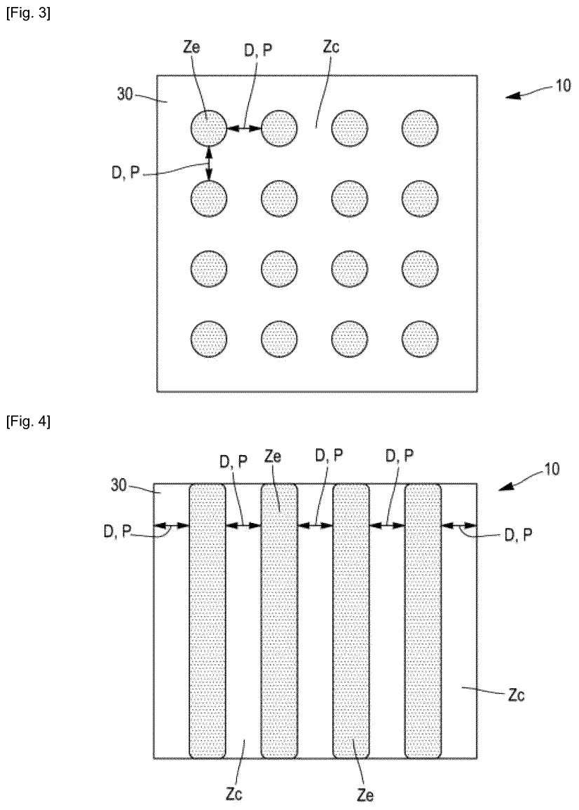

FIGS. 3 and 4 illustrate two non-limiting variants of support structures 10 in which the relief patterns 21 comprise bumps (FIG. 3) or domed ribs (FIG. 4). It is however possible to combine these two types of patterns with each other, or with other equivalent patterns.

The support structure 10 finally comprises a structured electrode 30, generally disposed on the relief patterns 21 and on the control electrode 5. The structured electrode 30 is metallic and made of a material different from the relief patterns 21. For example, the structured electrode 30 comprises indium-tin oxide (ITO), aluminum (Al), or equivalent.

The structured electrode 30 is arranged so as to have contact areas Zp at which the structured electrode 30 is directly in contact with the control electrode 5, and spacing areas Ze at each of which the structured electrode 30 is separated from the control electrode 5 by at least one of the relief patterns 21. The structured electrode 30 is therefore electrically conductive. For example, the structured electrode 30 comprises or is made of silver. Thus, the extraction of the plasmons is facilitated because they are less easily absorbed in the structured electrode 30. Generally, the structured electrode 30 is continuous, in particular electrically continuous. This means that the structured electrode 30 has substantially the same electrical potential over its entire extent.

By “structured” is meant that the structured electrode 30 has at least one non-planar surface (in the absence of filling material) which delimits a set of reliefs corresponding to the relief patterns 21. The variants of FIGS. 3 and 4 respectively illustrate embodiments in which the structured electrode 30 has a bumpy or corrugated upper face fs30. Thus, the production of the support structure 10 is simplified.

As indicated previously, and as can be seen in particular in FIGS. 1 and 2, the structured electrode 30 is separated from the control electrode 5 at the spacing areas Ze. Indeed, the relief patterns 21 are disposed between the control electrode 5 and the structured electrode 30 at the spacing areas Ze.

Conversely, at the contact areas Zp, the control electrode 5 and the structured electrode 30 are electrically connected. Generally, the control electrode 5 and the structured electrode 30 are in direct contact at the contact areas Zp.

The structured electrode 30 may have a lower face fi30 facing the contact face fc5 of the control electrode 5, which is opposite the upper face fs30. In this case, it is advantageous to provide that a height h2 at one of the spacing areas Ze is strictly greater than a height h1 at one of the contact areas Zp adjacent to said spacing area Ze, said heights h1, h2 being measured between the contact face fc5 and the upper face fs30 and substantially perpendicular to the contact face fc5. Thus, it is possible to guarantee a structuring of the upper face fs30 of the structured electrode 30 which is similar to the structuring of the relief patterns 21.

According to a non-limiting embodiment, the structured electrode 30 may have a substantially constant thickness denoted “e”. For example, the thickness e of the structured electrode 30 is comprised between 15 nm and 50 nm. Thus, it is possible to guarantee a structuring of the structured electrode 30 similar to the structuring of the relief patterns 21.

Each relief pattern 21 may have a maximum thickness e20x measured transversely to the contact face fc5 of the control electrode 5 comprised between 10 nm and 250 nm, and in particular between 30 nm and 100 nm. In this way, it is possible to guarantee that the thickness of the relief patterns is sufficiently low so as not to create an excessively large path difference between the contact areas Zp and the spacing areas Ze.

All of the arrangements described above make it possible to propose a support structure 10 capable of controlling the actuation of an optoelectronic device 1 by an electronic control device 3, which makes it possible to carry out a rapid and efficient light emission.

Indeed, the presence of a structured electrode 30 makes it possible to extract light linked to particular emission modes, and the value of the fixed pitch P separating the relief patterns 21 makes it possible to direct the light thus extracted in a preferred direction. Furthermore, it is possible to guarantee a continuity of the structured electrode 30 in contact with a light-emitting layer 41 of the optoelectronic device.

As indicated above, the invention also relates to an optoelectronic device 1, one embodiment of which is represented in FIG. 2. This optoelectronic device 1 comprises a support structure 10 of the type of one of those described previously, and a stack 40 of semiconductor layers disposed on the structured electrode 30 which forms a first electrode. The stack 40 comprises at least one light-emitting layer 41 configured to emit a light radiation around a predetermined wavelength. For example, said predetermined wavelength is comprised between 400 nm and 1000 nm.

Although not limited thereto, the stack 40 of semiconductor layers may comprise organic semiconductor layers and at least one organic light-emitting layer 41.

Advantageously, the predetermined fixed pitch P can be selected to orient the light extracted by the structured electrode in a preferred direction. For this, it is possible to select the pitch P according to the effective index of the plasmon mode n_{eff}, of the sine of the emission angle θ, of the emission wavelength λ of the light-emitting layer 41, and according to the following formula:

$$sin ( θ ) = \frac{{n}_{eff}}{λ} + \frac{K}{P} ,$$

where K is an integer. For example, the predetermined fixed pitch P may be substantially equal to the emission wavelength of the light-emitting layer 41. Generally, the effective index of the plasmon mode n_{eff} is comprised between 1.5 and 2. All of the arrangements previously described make it possible to excite a localized plasmon mode at said emission wavelength. The light emission is thus more efficient.

Furthermore, a distance separating the light-emitting layer 41 from the structured electrode 30 may be selected to be less than 80 nm, and in particular substantially equal to 30 nm. Thus, it is possible to maximize the Purcell effect, which makes it possible to improve the lifetime of the molecules present in the light-emitting layer 41, and in particular in the case of fluorescent molecules.

Synergistically, the use of a predetermined fixed pitch P substantially equal to the emission wavelength of the light-emitting layer 41, while placing this light-emitting layer 41 at a distance less than 80 nm, and in particular substantially equal to 30 nm, makes it possible both to make possible the excitation of a plasmon mode and to maximize the Purcell effect which are two a priori antagonistic effects.

Finally, the optoelectronic device 1 comprises a second electrode 6, generally at least partially transparent, and disposed on a surface of said stack 40 generally opposite the structured electrode 30. In this way, the structured electrode 30 and the second electrode 6 are configured to apply an electrical voltage to the stack 40 of semiconductor layers, in particular to allow light emission by the light-emitting layer 21. In other words, the first electrode and the second electrode 6 are arranged to allow the propagation of the electrical control signal through the stack 40.

All of the arrangements previously described make it possible to propose an optoelectronic device 1 in which the structuring of the structured electrode 30 makes it possible to minimize the distance D separating the light-emitting layer 41 from the structured electrode 30, while limiting the absorption by plasmonic coupling.

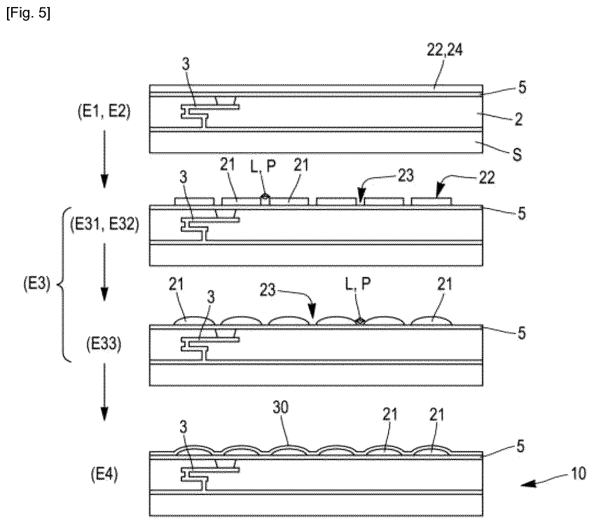

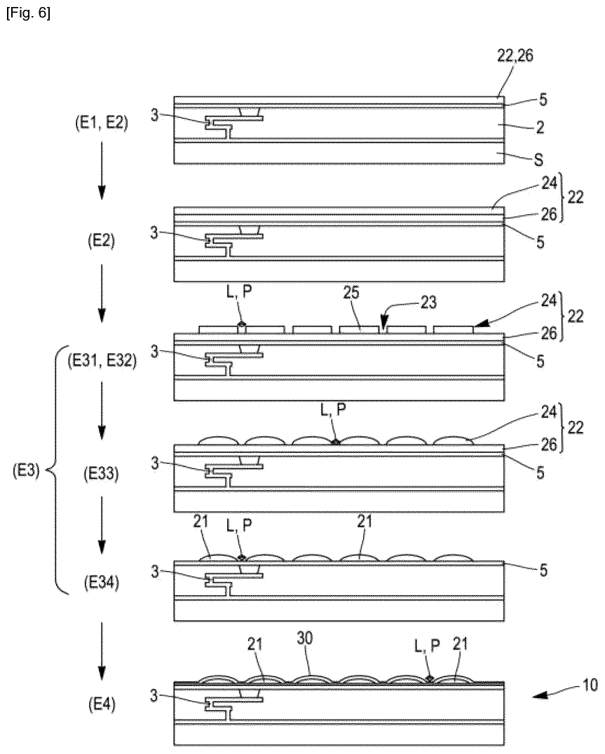

The invention also relates to a method for manufacturing a support structure 10 as described previously, two embodiments of which are presented in FIGS. 5 and 6.

Regardless of the embodiment, the manufacturing method firstly comprises a provision step E1 in which the electronic control device 3 is made available. Generally, the electronic control device 3 is encapsulated in the internal layer 2, itself deposited on the substrate S.

The manufacturing method then comprises an initial deposition step E2 in which at least one primary layer 22 is deposited on the control electrode 5 of the electronic control device 3.

According to the embodiment illustrated in FIG. 5, this initial deposition step E2 comprises the deposition of a resin 24, thus forming the primary layer 22.

According to the embodiment illustrated in FIG. 6, the initial deposition step E2 comprises the deposition of an interlayer insulating layer 26 on the control electrode 5 then of a resin 24 on the interlayer insulating layer 26. The primary layer 22 is thus formed by the superposition of the interlayer insulating layer 26, and of the resin layer 24. In this case, the primary layer 22 is electrically insulating.

The manufacturing method then comprises a step E3 of forming relief patterns in which portions 23 of said at least one primary layer 22 are removed from the control electrode 5. The portions 23 thus formed have a width L measured in a plane parallel to the control electrode 5 corresponding to an integer multiple of the predetermined fixed pitch P. The removal of said portions 23 thus forms, by complementarity, the relief patterns 21.

According to the embodiment of FIG. 5, the step E3 of forming relief patterns comprises:
an exposure step E31, in which said resin 24 is exposed through an exposure mask, and
a development step E32, in which the portions 23 of the primary layer 22 are removed by development in a development solvent to form, by complementarity, the relief patterns 21.

Alternatively, and as represented in FIG. 6, the step E3 of forming relief patterns may comprise:
an exposure step E31 in which said resin 24 is exposed through an exposure mask,
a development step E32 in which portions 23 of the resin 24 are removed by development in a development solvent to form, by complementarity, intermediate relief patterns 25, and
an etching step E34 in which the resin 24 and the interlayer insulating layer 26 are etched, by dry or wet etching, to form the relief patterns 21.

Such steps E3 of forming relief patterns correspond to photolithography methods used in microelectronic methods. It is therefore well understood that depending on the intended application, the person skilled in the art will select the resins, the exposure masks, and the solvents to remove by development the portions of the primary layer 22.

The previously described arrangements make it possible to define two alternative methods for forming the relief patterns 21 on a micrometric or nanometric scale.

Advantageously, the step E3 of forming relief patterns may comprise a creep step E33, implemented after the development step E32. During this creep step E33, the resin 24 is subjected to a heat treatment at a creep temperature, so as to round the relief patterns 21 or the intermediate relief patterns 25. In this way, it is possible to form rounded relief patterns 21 which limit the risk of breakage of the structured electrode 30, in particular when it has a low thickness e. It is therefore well understood that the formation of rounded relief patterns is particularly easy using the creep of a resin.

According to the embodiment of FIG. 6, the creep step E33 is implemented between the development step E32 and the etching step E34.

Finally, the manufacturing method comprises an electrode deposition step E4, in which the structured electrode 30 is deposited on the relief patterns and on the control electrode 5. Generally, such deposition is carried out by depositing a metal by a method selected from chemical vapor deposition (or CVD), plasma enhanced chemical vapor deposition (or PECVD), sputtering, physical vapor deposition (or PVD), pulsed laser assisted deposition (or PLD), said metal forming the structured electrode 30 by conforming to the structure formed by the relief patterns 21 on the control electrode 5.

The arrangements described above make it possible to propose a method for manufacturing a support structure 10 suitable for controlling the actuation of an optoelectronic device 1 by an electronic control device 3, allowing a rapid and efficient light emission.

The invention also relates to a method for manufacturing an optoelectronic device 1 as described previously. This manufacturing method comprises all of the steps of the method for manufacturing a support structure 10 described previously with reference to FIGS. 5 and 6.

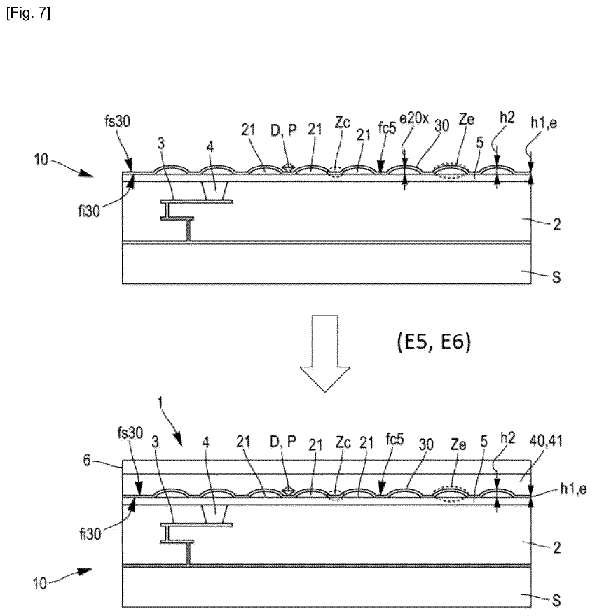

This method for manufacturing an optoelectronic device also comprises the following steps, illustrated in FIG. 7:
a step E5 of depositing a stack, in which a stack 40 of semiconductor layers is deposited on the structured electrode 30, said stack 40 comprising at least one light-emitting layer 41, the deposition of the light-emitting layer 41 during said step E5 of depositing a stack being carried out so that a distance separating the light-emitting layer 41 and the structured electrode 30 is less than 80 nm, and in particular substantially equal to 30 nm;
a second electrode deposition step E6, in which a second electrode 6 is deposited on the stack 40.

The method for manufacturing the optoelectronic device 1 comprises the fact that during the step E3 of forming relief patterns, the predetermined fixed pitch P is substantially equal to an emission wavelength of the light-emitting layer 41.

For example, the step E5 of depositing a stack can be carried out by thermal evaporation. In this case, each layer of the stack 40 is deposited by evaporation of the material corresponding to said layer. For this, the material is in a crucible which is heated by the Joule effect, in order to reach the evaporation temperature of the material, for example organic.

Each layer has a very specific function in the stack 40 thanks to its optoelectronic properties.

For example, the stack 40 may comprise the stack of the following layers: HIL/HTL/EBL/EL/HBL/ETL/EIL.

With:
HIL for Hole Injection Layer, for example molybdenum trioxide (MoO₃);
HTL for Hole Transporting Layer, for example STTB;
EBL for Electron Blocking Layer, for example NPB;
EL for the light-emitting layer 41, for example doped or undoped Alq₃;
HBL for Hole Blocking Layer, for example BCP;
ETL for Electron Transporting Layer, for example Bphen;
EIL for Electron Injection Layer, for example a metallic element.

During the second electrode deposition step E6, it is possible that the second electrode 6 comprises aluminum (Al) or silver (Ag), or equivalent.

In general, the manufacturing method may comprise a step of depositing an encapsulation layer (not represented), for example a layer of Al₂O₃, for example deposited by an ALD (Atomic Layer Deposition) technique.

1. An optoelectronic device comprising:
a support structure comprising:
an electronic control device comprising a control electrode substantially planar and intended for transmitting an electrical control signal to a stack of semiconductor layers, the electronic control device being configured to generate the electrical control signal;
relief patterns arranged on the control electrode, each of the relief patterns being separated from at least one other of the relief patterns by a distance corresponding to an integer multiple of a predetermined fixed pitch; and
a metallic structured electrode of a material different from the relief patterns, the structured electrode being arranged so as to have contact areas at which the structured electrode is directly in contact with the control electrode and spacing areas at each of which the structured electrode is separated from the control electrode by at least one of the relief patterns;
the stack of semiconductor layers disposed on the structured electrode forming a first electrode, the stack comprising at least one light-emitting layer; and
a second electrode disposed on the stack;
the first electrode and the second electrode being arranged to allow the propagation of the electrical control signal through the stack;
the optoelectronic device in which the predetermined fixed pitch is substantially equal to an emission wavelength of the light-emitting layer, and in which a distance separating the light-emitting layer and the structured electrode is less than 80 nm.

2. The optoelectronic device according to claim 1, wherein the relief patterns comprise an insulating material.

3. The optoelectronic device according to claim 1, wherein the relief patterns are disposed periodically on the control electrode according to a period corresponding to the same integer multiple of the predetermined fixed pitch.

4. The optoelectronic device according to claim 1, wherein the relief patterns are rounded.

5. The optoelectronic device according to claim 1, wherein the electronic control device comprises a transistor.

6. The optoelectronic device according to claim 1, wherein each relief pattern has a maximum thickness measured transversely to the contact face of the control electrode which is comprised between 50 nm and 250 nm.

7. The optoelectronic device according to claim 1, wherein the relief patterns comprise bumps and/or domed ribs, so that the structured electrode has a bumpy and/or corrugated upper face.

8. The optoelectronic device according to claim 7, wherein the stack of semiconductor layers comprises organic semiconductor layers and at least one organic light-emitting layer.

9. The optoelectronic device according to claim 8, wherein a distance separating the light-emitting layer and the structured electrode is less than 80 nm.

10. A method for manufacturing an optoelectronic device according to claim 1, the manufacturing method comprising:
a provision step in which the electronic control device is made available;
an initial deposition step in which at least one primary layer is deposited on the control electrode of the electronic control device;
a step of forming relief patterns in which portions of the at least one primary layer are removed from the control electrode, the portions having a width measured in a plane parallel to the control electrode, the width corresponding to an integer multiple of a predetermined fixed pitch, the removal of said portions forming, by complementarity, the relief patterns;
a first electrode deposition step, in which the structured electrode is deposited on the relief patterns and on the control electrode;
a step of depositing a stack, in which a stack of semiconductor layers is deposited on the structured electrode, the stack comprising at least one light-emitting layer, the deposition of the light-emitting layer during the step of depositing a stack being carried out so that a distance separating the light-emitting layer and the structured electrode is less than 80 nm;
a second electrode deposition step, in which a second electrode is deposited on the stack;
the manufacturing method wherein during the step of forming relief patterns, the predetermined fixed pitch is substantially equal to an emission wavelength of the light-emitting layer.

11. The manufacturing method according to claim 10, wherein the primary layer deposited during the initial deposition step comprises a resin, the step of forming relief patterns then comprising:
an exposure step, in which the resin is exposed through an exposure mask, and
a development step, in which the portions of the primary layer are removed by development in a development solvent to form, by complementarity, the relief patterns.

12. The manufacturing method according to claim 10, wherein the initial deposition step comprises the deposition of an interlayer insulating layer on the control electrode then of a resin on the interlayer insulating layer, the step of forming relief patterns then comprising:
an exposure step in which the resin is exposed through an exposure mask,
a development step in which portions of the resin are removed by development in a development solvent to form, by complementarity, intermediate relief patterns, and
an etching step in which the resin and the interlayer insulating layer are etched to form the relief patterns.

13. The manufacturing method according to claim 11, wherein the step of forming relief patterns comprises a creep step, implemented after the development step, in which the resin is subjected to a heat treatment at a creep temperature, so as to round the relief patterns or the intermediate relief patterns.
